(19) United States
(12) Patent Application Publication
(10) Pub. No.: US 2011/0057715 A1
(43) Pub. Date: Mar. 10, 2011

(54) HIGH BANDWIDTH SWITCH DESIGN

(75) Inventor: Dianbo GUO, Singapore (SG)

(73) Assignee: STMicroelectronics Asia Pacific Pte Ltd., Singapore (SG)

(21) Appl. No.: 12/555,601

(22) Filed: Sep. 8, 2009

(51) Int. Cl. H03K 17/687

(52) U.S. Cl. 327/434

(57) ABSTRACT

An analog switch includes a transistor having a current path between an input and an output, a gate coupled to a control terminal, and a bulk terminal, and a switched bulk control circuit coupled to the control terminal, the bulk terminal, and ground to reduce an equivalent capacitance seen from a source terminal or drain terminal of the transistor towards the bulk terminal of the transistor. The bulk control circuit includes an all-NMOS bulk control circuit if an NMOS transistor switch is used.

### BACKGROUND OF THE INVENTION

The present invention is related to analog circuits, and, more particularly, to analog switches. Analog switches are widely used as basic circuit components in analog integrated circuit design. Analog switches can provide great design flexibility at the system level. When used in high speed applications, such as USB, LAN and DisplayPort, among others, a high bandwidth switch is required. In order to achieve high bandwidth, either an NMOS or a PMOS transistor is used as switch, instead of using a complementary NMOS and PMOS pair, depending upon a specified input signal range. With a defined on-resistance, in order to achieve high bandwidth, conventionally a series resistor is inserted between the gate of the transistor switch and the gate control circuit.

Referring now FIG. 1, a normal prior art complementary analog switch is shown. The switch in FIG. 1 includes an NMOS transistor M1 having a current path between the input and the output of the switch, and a PMOS transistor M0 having a current path between the input and the output of the switch. The gate control for transistor M1 is provided by the NG_CTL signal, and the gate control for transistor M0 is provided by the PG_CTL signal. When the NMOS gate control signal NG_CTL is connected to ground and the PMOS gate control signal PG_CTL is connected to VDD, the switch shown in FIG. 1 is off. When the NMOS gate control signal NG_CTL is connected to VDD and the PMOS gate control signal PG_CTL is connected to ground, the switch shown in FIG. 1 is on.

Referring now to FIG. 2, an equivalent circuit of the analog switch of FIG. 1 is shown. When analog switch is on, it is equivalent to a low pass filter, represented as a resistor, R0, and a capacitor, C0 to ground. Capacitor C0 can be placed either at the input side or the output side of the equivalent circuit. Assume that the source impedance, RS, and the load impedance RL are equal, and the value is R. They are much larger compared to R0.

Referring again to FIG. 2, the switch bandwidth is represented by the following formula:

$$Bandwidth = \frac{2 R + Ro}{RCo ( R + Ro )} ≅ \frac{2}{( R + Ro ) Co} ≅ \frac{2}{RCo}$$

Referring now to FIG. 3, the parasitic capacitances associated with the normal analog switch are analyzed. For an analog switch, there are six different sources of parasitic capacitance:

1. Source to gate capacitance, Csg;

2. Source to bulk capacitance, Csb;

3. Drain to gate capacitance, Cdg;

4. Drain to bulk capacitance, Cdb;

5. IO ESD protection capacitance;

6. Package capacitance.

The ESD protection capacitance and the package capacitance depend upon the technology used and are not discussed further.

Referring now to FIG. 4, an equivalent circuit for an analog switch is shown including all of the above parasitic capacitances. Resistor R0 is the resistance between the source and drain (input and output), capacitor C0 is the gate capacitance, and C1 is the bulk capacitance, wherein:

C0=Csg+Cdg; and

C1=Csb+Cdb

Referring now to FIG. 5, a prior art NMOS switch is shown. NMOS switch includes an NMOS transistor M1 having a current path coupled between the input and output. The bulk connection of transistor M1 is coupled to ground. The NG_CTL signal is used to turn the switch on and off. By inserting a series resistor R1 between the NMOS transistor gate and the gate control signal NG_CTL, higher bandwidth is achieved.

Referring now to FIG. 6, an equivalent circuit of the NMOS switch is shown including R0 equal to five ohms, capacitor C0 equal to five picofarads, gate resistor R1, and capacitor C1 equal to five picofarads.

Referring now to FIG. 7, simulations results are providing showing the output voltage of the NMOS switch versus frequency. For the equivalent circuit conditions where a five ohm switch is desired, and it is assumed that capacitor C1 is equal to C0, simulation results show that the switch bandwidth is a maximum with R1 equal to 1K Ω. Referring to FIG. 8 the bandwidth for different values of R1 are shown. For a value of zero ohms, the bandwidth is 607 MHz. For a value of one ohm, the bandwidth is 600 MHz. For a value of ten ohms, the bandwidth is 560 MHz. For a value of one hundred ohms, the bandwidth is 750 MHz. For a value of one thousand ohms, the bandwidth is 1180 MHz.

While two conventional analog switches are shown, with corresponding techniques for improving bandwidth, the performance demands of modern analog integrated circuits require new analog switching circuits to further increase bandwidth.

### SUMMARY OF THE INVENTION

According to a first embodiment of the present invention a bulk control circuit for an analog switch having an input, an output, a bulk terminal, and a control terminal, includes a first transistor having a current path coupled between the input and the bulk terminal, and a gate coupled to the control terminal, a second transistor having a current path coupled between the output and the bulk terminal, and a gate coupled to the control terminal, a third transistor having a current path coupled between the bulk terminal and ground, and a gate, and an inverter having an input coupled to the control terminal, and an output coupled to the gate of the third transistor. The first, second, and third transistors are NMOS transistors. The bulk terminal of the first, second, and third transistors is coupled to ground. The analog switch includes an NMOS transistor having a current path between the input and output, and having a gate coupled to the control terminal. The analog switch also includes a resistor interposed between the control terminal and the gate.

According to a second embodiment of the present invention, a bulk control circuit for an analog switch having an input, an output, a bulk terminal, and a control terminal, includes a first transistor having a current path coupled between the bulk terminal and ground, and a gate, a second transistor having a current path coupled between the bulk terminal and ground, and a gate coupled to the control terminal, and an inverter having an input coupled to the control terminal and an output coupled to the gate of the first transistor. The first and second transistors are NMOS transistors. The bulk terminal of the first and second transistors is coupled to ground. The analog switch includes an NMOS transistor having a current path between the input and output, and having a gate coupled to the control terminal. The analog switch also includes a resistor interposed between the control terminal and the gate.

According to a third embodiment of the present invention, a bulk control circuit for an analog switch having an input, an output, a bulk terminal, and a control terminal, includes a first transistor having a current path coupled between the bulk terminal and ground, and a gate, a second transistor having a current path coupled between the bulk terminal and ground, and a gate coupled to a source of supply voltage, and an inverter having an input coupled to the control terminal and an output coupled to the gate of the first transistor. The first and second transistors are NMOS transistors. The bulk terminal of the first and second transistors is coupled to ground. The analog switch includes an NMOS transistor having a current path between the input and output, and having a gate coupled to the control terminal. The analog switch also includes a resistor interposed between the control terminal and the gate.

In summary, according to the present invention, an analog switch includes a transistor having a current path between an input and an output, a gate coupled to a control terminal, and a bulk terminal, and a switched bulk control circuit coupled to the control terminal, the bulk terminal, and ground to reduce an equivalent capacitance seen from a source terminal or drain terminal of the transistor towards the bulk terminal of the transistor. The bulk control circuit includes an all-NMOS bulk control circuit.

### BRIEF DESCRIPTION OF THE DRAWINGS

The present invention is illustrated by way of example and not by limitation in the accompanying figures in which like reference numerals indicate similar elements and in which:

FIG. 1 is a schematic diagram of a prior art complementary analog switch;

FIG. 2 is an equivalent circuit of the analog switch shown in FIG. 1;

FIGS. 3 and 4 are equivalent circuits illustrating the parasitic capacitances associated with the analog switch shown in FIG. 1;

FIG. 5 is a schematic diagram of a prior art NMOS analog switch;

FIG. 6 is an equivalent circuit of the analog switch shown in FIG. 5;

FIG. 7 is a simulation graph showing output voltage versus frequency for the analog switch shown in FIG. 5;

FIG. 8 is a table associated with the simulations results of FIG. 7;

FIG. 9 is a schematic diagram of a first embodiment of an analog switch according to the present invention;

FIGS. 10 and 11 are equivalent circuits of the analog switch shown in FIG. 9;

FIG. 12 is a schematic diagram of a second embodiment of an analog switch according to the present invention;

FIG. 13 is an equivalent circuit of the analog switch shown in FIG. 12;

FIG. 14 is a schematic diagram of a third embodiment of an analog switch according to the present invention;

FIG. 15 is an equivalent circuit of the analog switch shown in FIG. 14.

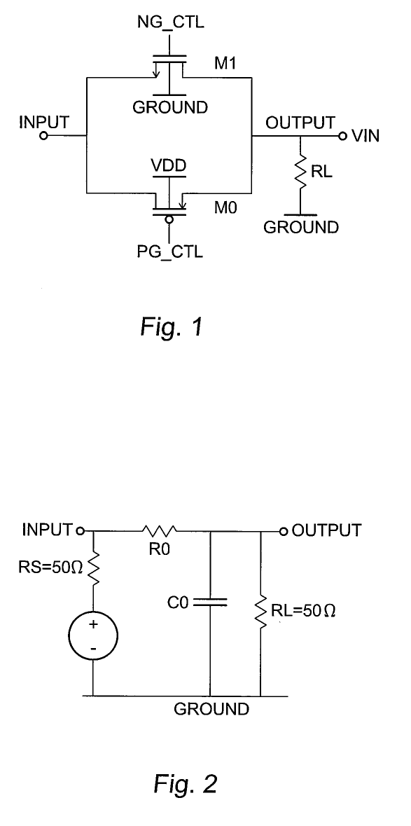

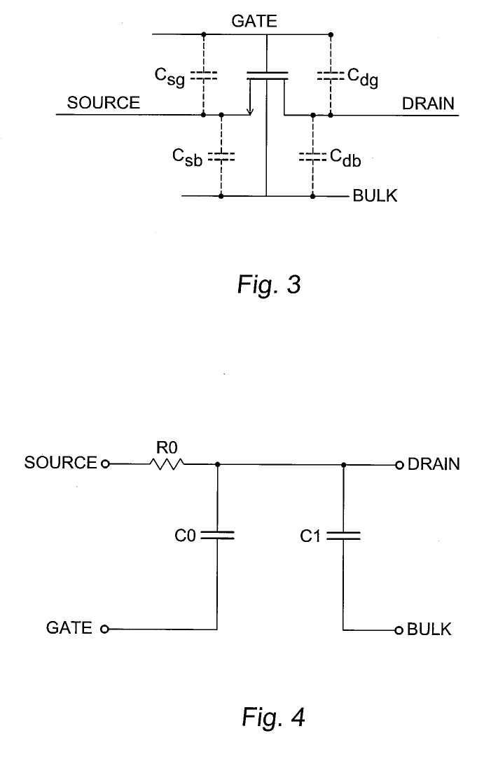

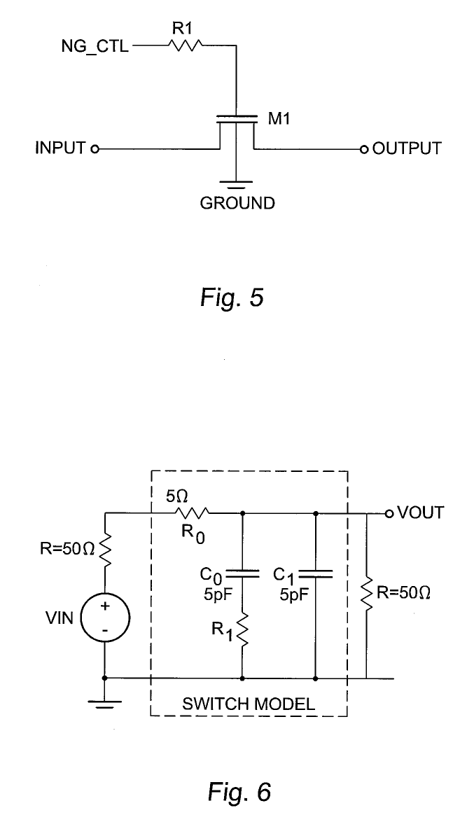

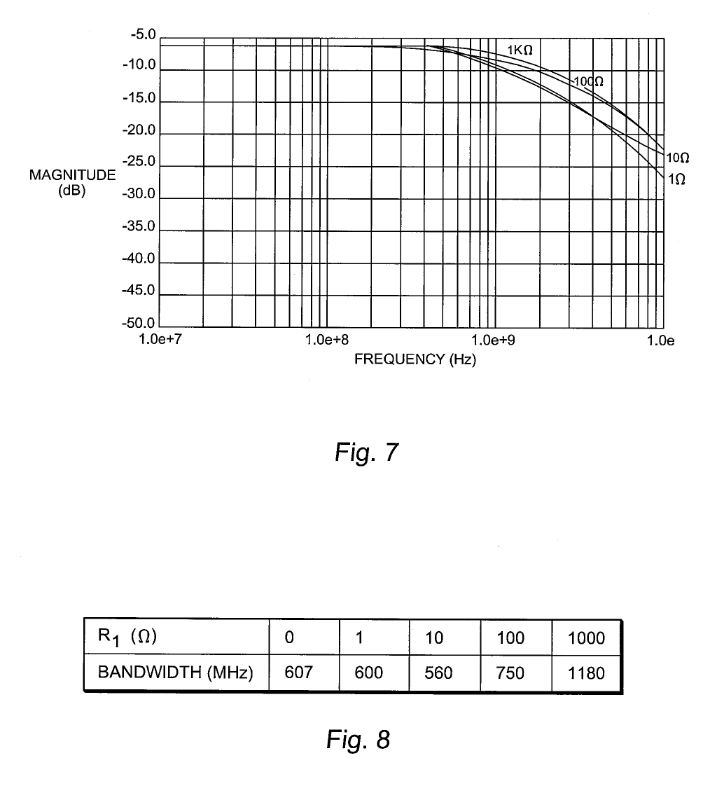

### DETAILED DESCRIPTION

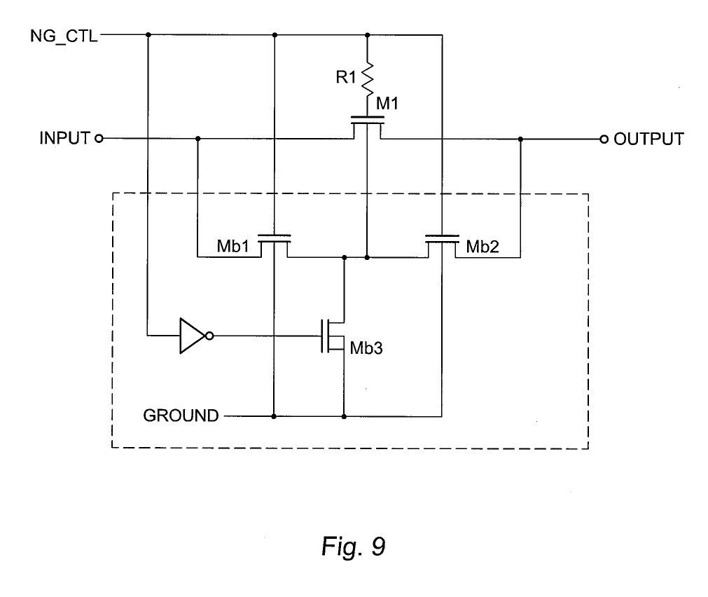

Referring now to FIG. 9, a first embodiment of an analog switch according to the present invention is shown. The switch includes an NMOS transistor M1, gate resistance R1, and control signal NG_CTL as previously described. A bulk control circuit for the analog switch has an input, an output, a bulk terminal, and a control terminal. The bulk control circuit includes a first transistor Mb1 having a current path coupled between the input and the bulk terminal, and a gate coupled to the control terminal, a second transistor Mb2 having a current path coupled between the output and the bulk terminal, and a gate coupled to the control terminal, a third transistor Mb3 having a current path coupled between the bulk terminal and ground, and a gate, and an inverter having an input coupled to the control terminal, and an output coupled to the gate of the third transistor. The first, second, and third transistors are NMOS transistors. The bulk terminal of the first, second, and third transistors in the bulk control circuit is coupled to ground.

In operation, when the switch is on, the NMOS transistor M1 bulk is shorted to the input and output terminals through transistors Mb1 and Mb2. The size of transistors Mb1 and Mb2 should be small in order to minimize port capacitance. When the switch is off, the NMOS transistor bulk is shorted to ground through transistor Mb3. The size of transistor Mb3 should be large enough to minimize transistor Mb3 on-resistance so that transistor M1 bulk can be shorted to ground through a low-resistance path.

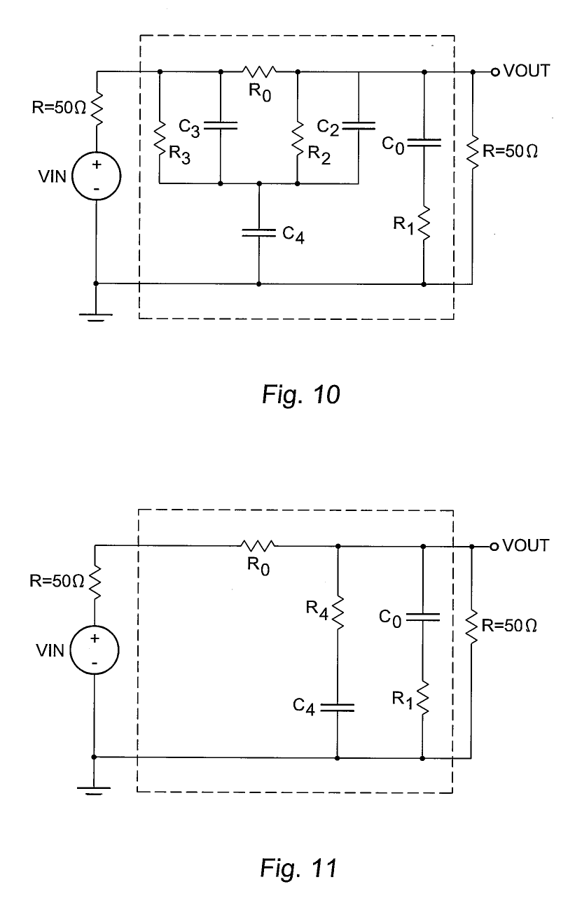

Referring now to FIGS. 10 and 11, equivalent circuits are shown for the analog switch of FIG. 9. In FIG. 10, the source to bulk capacitor and drain to bulk capacitor, C2 and C3 are in parallel with resistors R2 and R3. The substrate (which is biased to ground) to bulk capacitor is represented as capacitor C4. A further simplified equivalent circuit is shown in FIG. 11. Resistor R4 represents the source/drain terminal to bulk resistor. Capacitor C4 represents the bulk to substrate capacitor.

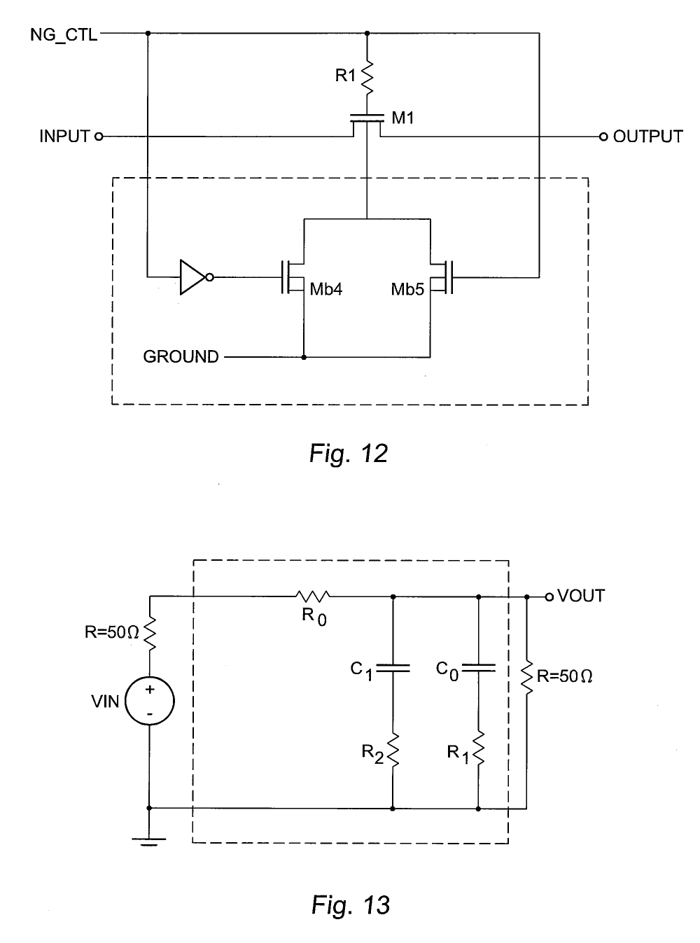

Referring now to FIG. 12, a bulk control circuit according to a second embodiment of the present invention is shown for an NMOS analog switch having an input, an output, a bulk terminal, and a control terminal. The bulk control circuit includes a first transistor Mb4 having a current path coupled between the bulk terminal and ground, and a gate, and a second transistor Mb5 having a current path coupled between the bulk terminal and ground, and a gate coupled to the control terminal, and an inverter having an input coupled to the control terminal and an output coupled to the gate of the first transistor. The first and second transistors are NMOS transistors. The bulk terminal of the first and second transistors is coupled to ground.

In operation, when the switch is on, the NMOS transistor M1 bulk is shorted to ground through transistor Mb5. The size of transistor Mb5 should be small such that Mb5 on-resistance is higher than at least 100 Ω. When the switch is off, the NMOS transistor M1 bulk is shorted to ground through transistor Mb4. The size of transistor Mb4 should be large enough to minimize transistor Mb4 on-resistance so that M1 transistor bulk can be shorted to ground through a low-resistance path.

Referring now to FIG. 13, an equivalent circuit is shown for the analog switch of FIG. 12, including a series resistance R0, capacitor C1 and resistor R2 representing transistor Mb4, and capacitor C0 and resistor R1 representing transistor Mb5.

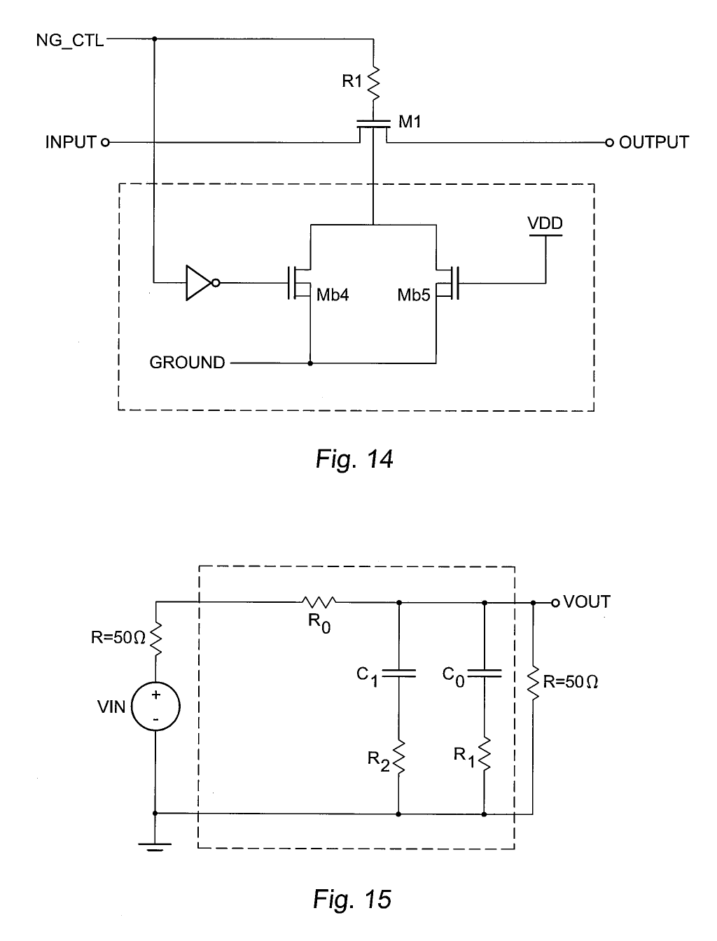

Referring now to FIG. 14, a bulk control circuit is shown according to a third embodiment of the invention. The same components as are used as in FIG. 12, except that the gate of transistor Mb5 gate is coupled to the power supply VDD instead of to the control signal. When the switch is on, the bulk of transistor M1 is shorted to ground through transistor Mb5 only. When the switch is off, the bulk of transistor M1 is shorted to ground through transistors Mb5 and Mb4. Referring to FIG. 15, the equivalent circuit is essentially the same as the equivalent circuit shown in FIG. 13.

In conclusion, the principle behind the first, second, and third embodiments of the present invention is to insert a series resistor between capacitor C1 and ground, wherein C1 is the sum of the source and drain to bulk capacitance. By doing so, higher bandwidth can be achieved. In the first embodiment, the bulk terminal and source and drain of the transistor switch are shorted together when the switch is on. In the second and third embodiments, the bulk terminal is shorted to ground through a resistor. When the switch is on, the resistor value is relatively larger, and so the equivalent capacitance seen from the source/drain terminals towards the bulk terminal is smaller at high frequency. When a PMOS transistor is used as a switch, a similar PMOS bulk control circuit can be employed to improve bandwidth. As those skilled in the art would know how to “flip” the circuit in this manner, the PMOS version of the switch and bulk control circuit is not described in further detail.

Although an embodiment of the present invention has been described for purposes of illustration, it should be understood that various changes, modification and substitutions may be incorporated in the embodiment without departing from the spirit of the invention that is defined in the claims, which follow.

We claim:

1. A bulk control circuit for an analog switch having an input, an output, a bulk terminal, and a control terminal, the circuit comprising:
a first transistor having a current path coupled between the input and the bulk terminal, and a gate coupled to the control terminal;
a second transistor having a current path coupled between the output and the bulk terminal, and a gate coupled to the control terminal;
a third transistor having a current path coupled between the bulk terminal and ground, and a gate; and
an inverter having an input coupled to the control terminal, and an output coupled to the gate of the third transistor.

2. The circuit of claim 1 wherein the first, second, and third transistors comprise NMOS transistors.

3. The circuit of claim 1 wherein the bulk terminal of the first, second, and third transistors is coupled to ground.

4. The circuit of claim 1 wherein the analog switch comprises an NMOS transistor having a current path between the input and output.

5. The circuit of claim 1 wherein the analog switch comprises an NMOS transistor having a gate coupled to the control terminal.

6. The circuit of claim 5 wherein the analog switch comprises a resistor interposed between the control terminal and the gate.

7. A bulk control circuit for an analog switch having an input, an output, a bulk terminal, and a control terminal, the circuit comprising:
a first transistor having a current path coupled between the bulk terminal and ground, and a gate;
a second transistor having a current path coupled between the bulk terminal and ground, and a gate coupled to the control terminal; and
an inverter having an input coupled to the control terminal and an output coupled to the gate of the first transistor.

8. The circuit of claim 7 wherein the first and second transistors comprise NMOS transistors.

9. The circuit of claim 7 wherein the bulk terminal of the first and second transistors is coupled to ground.

10. The circuit of claim 7 wherein the analog switch comprises an NMOS transistor having a current path between the input and output.

11. The circuit of claim 7 wherein the analog switch comprises an NMOS transistor having a gate coupled to the control terminal.

12. The circuit of claim 11 wherein the analog switch comprises a resistor interposed between the control terminal and the gate.

13. A bulk control circuit for an analog switch having an input, an output, a bulk terminal, and a control terminal, the circuit comprising:
a first transistor having a current path coupled between the bulk terminal and ground, and a gate;
a second transistor having a current path coupled between the bulk terminal and ground, and a gate coupled to a source of supply voltage; and
an inverter having an input coupled to the control terminal and an output coupled to the gate of the first transistor.

14. The circuit of claim 13 wherein the first and second transistors comprise NMOS transistors.

15. The circuit of claim 13 wherein the bulk terminal of the first and second transistors is coupled to ground.

16. The circuit of claim 13 wherein the analog switch comprises an NMOS transistor having a current path between the input and output.

17. The circuit of claim 13 wherein the analog switch comprises an NMOS transistor having a gate coupled to the control terminal.

18. The circuit of claim 17 wherein the analog switch comprises a resistor interposed between the control terminal and the gate.

19. An analog switch comprising:
a transistor having a current path between an input and an output, a gate coupled to a control terminal, and a bulk terminal; and
a switched bulk control circuit coupled to the control terminal, the bulk terminal, and ground to reduce an equivalent capacitance seen from a source terminal or drain terminal of the transistor towards the bulk terminal of the transistor.

20. The analog switch of claim 19 wherein the bulk control circuit comprises an all-NMOS bulk control circuit.
